(19) United States
(12) Patent Application Publication
(10) Pub. No.: US 2014/0026009 A1
(43) Pub. Date: Jan. 23, 2014

(54) INTEGRATED CIRCUIT AND TEST SYSTEM THEREOF

(71) Applicant: NOVATEK MICROELECTRONICS CORP., Hsinchu (TW)

(72) Inventors: Jhih-Siou CHENG, New Taipei City (TW); Pang-Chan Hung, Kaohsiung City (TW)

(73) Assignee: NOVATEK MICROELECTRONICS CORP., Hsinchu (TW)

(21) Appl. No.: 13/843,186

(22) Filed: Mar. 15, 2013

(30) Foreign Application Priority Data
Jul. 19, 2012 (TW) 101126071

(51) Int. Cl. G01R 31/3177

(52) U.S. Cl. CPC G01R 31/3177
USPC 714/733

(57) ABSTRACT

An integrated circuit includes an input unit, a core processor and M output buffers, where M is a natural number greater than 1. The input unit has an output control pin, and receives an output control signal. The core processor is coupled to the input unit, and receives the output control signal to provide M output control signals. The M output buffers are coupled to the core processor, and are time-division multiplexing and enabled in response to the M output control signals, respectively, to output M output signals in M operation periods, respectively.

This application claims the benefit of Taiwan application Serial No. 101126071, filed Jul. 19, 2012, the subject matter of which is incorporated herein by reference.

### TECHNICAL FIELD

The application relates to an integrated circuit and a test system thereof.

### BACKGROUND

In the modern world of constantly progressing technologies, various kinds of integrated circuit are developed to bring convenience to people's daily life. In general, a signal from an output pin of an integrated circuit needs to be tested to ensure that a desired operation can be correctly performed.

As geometric sizes of chip fabrication process continue to decrease, the number of operation functions as well as output and input pin-counts of an integrated circuit correspondingly increase. Thus, a test machine for testing IC functions needs to be upgraded in order to adequately handle the increasing IC pin-count. Consequently, issues of costly tests and an insufficient test throughput of the test machine are often resulted.

### SUMMARY

According to an embodiment of the present application, an integrated circuit is provided. The integrated circuit includes an input unit, a core processor and M output buffers, where M is a natural number greater than 1. The input unit has an output control pin, and receives an output control signal. The core processor is coupled to the input unit, and receives the output control signal to provide M output control signals. The M output buffers are coupled to the core processor, and are time-division multiplexing and enabled in response to the M output control signals, respectively, to output M output signals in M operation periods, respectively.

According to another embodiment of the present application, a test system is provided. The test system includes a test apparatus, a bridge unit and an integrated circuit. The test apparatus includes a control unit for providing an output control signal. The bridge unit includes a switching unit having N inputs and an output, where N is a natural number greater than 1. The integrated circuit includes an input unit, a core processor and M output buffers, where M is a natural number greater than 1 and smaller than or equal to N. The input unit has an output control pin, and receives an output control signal. The core processor is coupled to the input unit, and receives the output control signal to provide M output control signals. The M output buffers are coupled to the N inputs, and are time-division multiplexing and enabled in response to the M output control signals, respectively, to output M output signals in M operation periods, respectively.

The above and other contents of the application will become better understood with regard to the following detailed description of the preferred but non-limiting embodiments. The following description is made with reference to the accompanying drawings.

### BRIEF DESCRIPTION OF THE DRAWINGS

FIG. 1 is a block diagram of a test system according to one exemplary embodiment.

FIG. 2 is a timing diagram of associated signals of the test system in FIG. 1.

FIG. 3A is a block diagram of a test system according to another exemplary embodiment.

FIG. 3B is a block diagram of a test system according to yet another exemplary embodiment.

FIG. 4 is a block diagram of a test system according to yet another exemplary embodiment.

FIG. 5 is a block diagram of a test system according to yet another exemplary embodiment.

FIG. 6 is a block diagram of a test system according to yet another exemplary embodiment.

FIG. 7 is a block diagram of a test system according to yet another exemplary embodiment.

### DETAILED DESCRIPTION OF THE APPLICATION

According to one embodiment of the present application, a test system is capable of designing a mechanism for selectively controlling an output of an integrated circuit to enter a high-impedance state on an integrated circuit under test or on a probe card. By appropriately controlling a part of pins of the integrated circuit at a high-impedance state, the test system according to one embodiment further implements a test operation on multiple pins under test in the integrated circuit using a single test module of a single test apparatus.

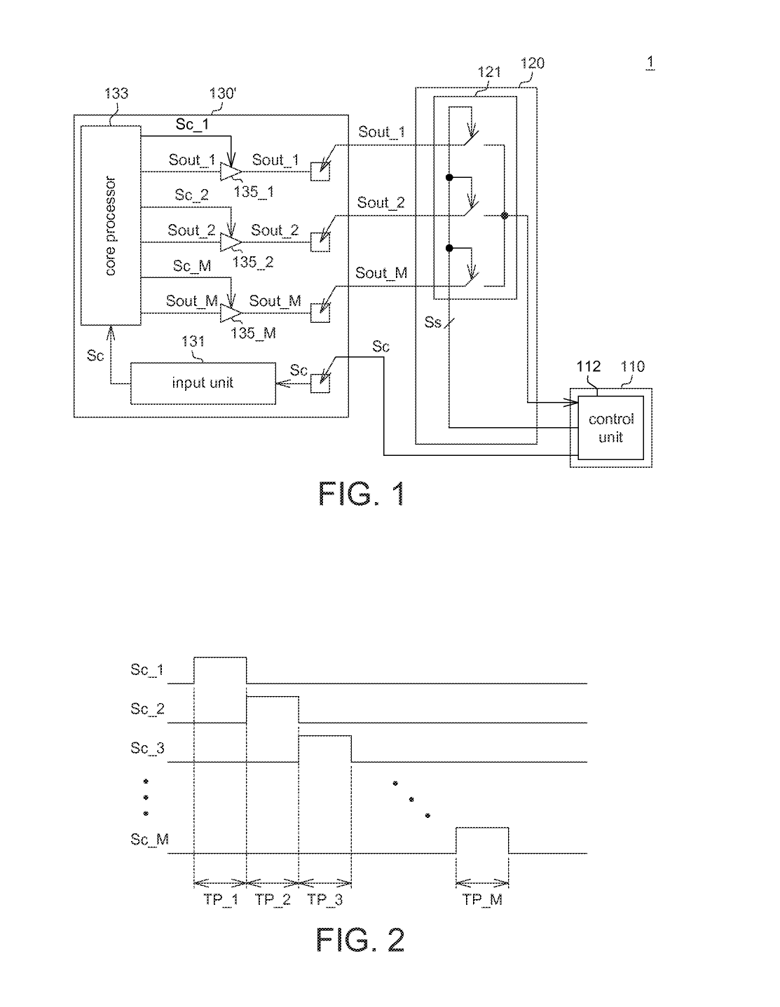

FIG. 1 shows a block diagram of a test system according to an exemplary embodiment. A test system 1 of the embodiment includes a test apparatus 100, a probe card 120 and an integrated circuit 130 under test. The integrated circuit 130 under test is connected to the test apparatus 100 via the probe card 120.

The probe card 120 includes a switching unit 121. The switching unit 121 has N inputs and an output, where N is a natural number greater than 1. The switching unit 121 further selectively couples one of the N inputs to the output in response to a switching control signal Ss. In other words, the probe card 120 has an external input high-impedance mechanism, so as to selectively couple one of the inputs to the output and to render other inputs to be at a high-impedance state.

The test apparatus 110 further includes a control unit 112 for providing an output control signal Sc, and for providing the switching control signal Ss for controlling switching operation of the switching unit 121.

The integrated circuit 130 under test includes an input unit 131, a core processor 133 and output buffers 135_1, 135_2, . . . and 135_M, where M is a natural number smaller than or equal to N. In FIG. 1, an exemplary situation of M=N is depicted. The input unit 131 has an output control pin and receives the output control signal Sc.

The core processor 133 is coupled to the input unit 131 for receiving the output control signal Sc to accordingly generate M output signals Sc_1, Sc_2, . . . and Sc_M. The core processor 133 provides the M output signals Sc_1, Sc_2, . . . and Sc_M to the output units 135_1 to 135_M, respectively. For example, the core processor 133 serves as a master control device for controlling operations of the integrated circuit 130 under test.

The output buffers 135_1 to 135_M are coupled to the core processor 133, and are respectively coupled to M inputs among the N inputs of the switching unit 121. In response to the M output control signals Sc_1 to Sc_M, the M output buffers 135_1 to 135_M are enabled in time-division multiplexing to output M output signals Sout_1 to Sout_M in M operation periods TP_1, TP, 2 . . . and TP_M to the M inputs of the switching unit 121, respectively.

For example, each of the output buffers 135_1 to 135_M may be implemented by a tri-state buffer. In one embodiment, each of the output buffers 135_1 to 135_M is a high-logic-triggered tri-state buffer, and signal waveforms of the output control signals Sc_1 to Sc_M may be as shown as FIG. 2. In other words, the integrated circuit 130 under test is designed with an internal input high-impedance mechanism, so as to selectively enable one of the output buffers 135_ to 135_M and to render other output buffers to be substantially at a high-impedance state.

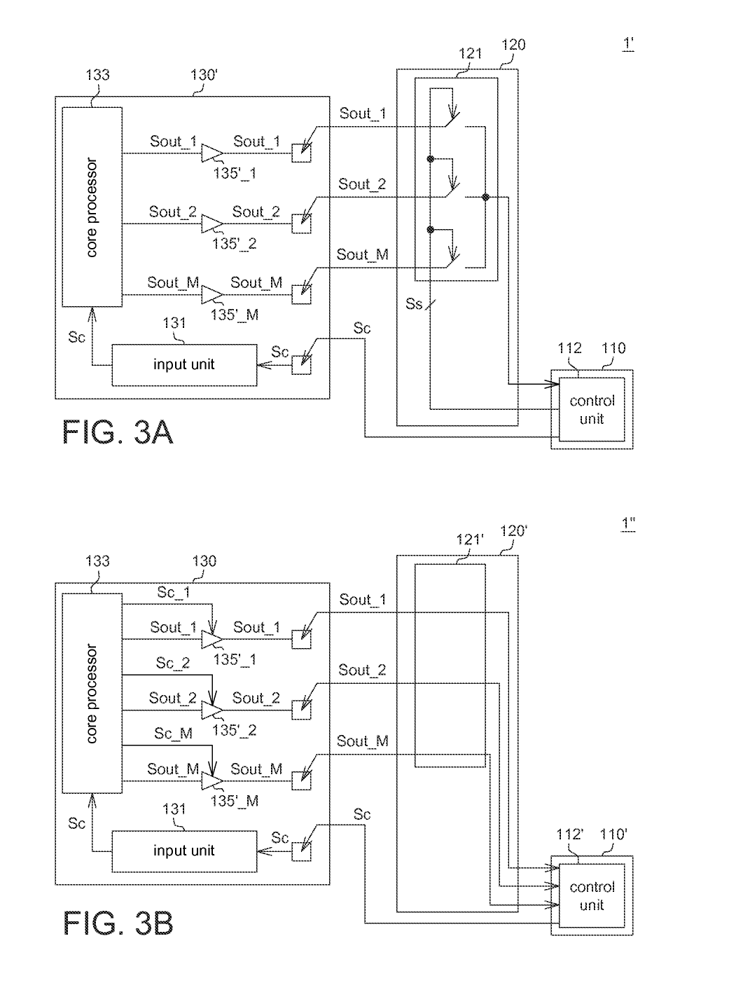

In the embodiment, a example that the probe card 120 having an external input high-impedance mechanism and the integrated circuit 130 under test having an internal input high-impedance mechanism is described as an example rather than a limitation to the test system 1 of the embodiment. In an alternative embodiment, a test system 1′ may also be selectively provided with either the external or internal input high-impedance mechanism, as shown in FIG. 3A and FIG. 3B.

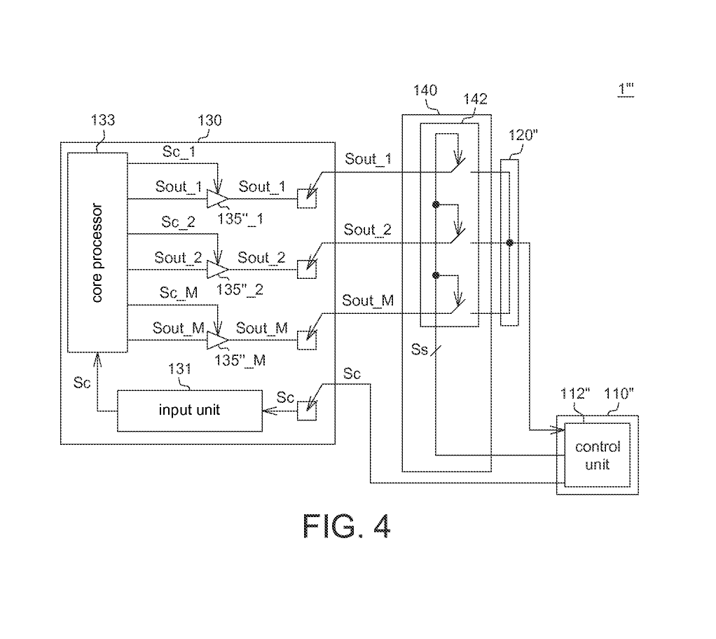

In the embodiment, the probe card 120 includes the switching unit 121, and the integrated circuit 130 under test is coupled to the test system 100 via the probe card 120, which are given as an example rather than a limitation to the test system 100 of the embodiment. In an alternative embodiment, a switching unit 142 is disposed in a bridge integrated circuit 140, and a test apparatus 110″ is coupled to an integrated circuit 130″ via the bridge integrated circuit 140 and a probe card 120″, as shown in FIG. 4. In other words, the switching unit 142 of a test system 1′″ according to the embodiment may also be integrated to the bridge integrated circuit 140, and the integrated circuit 130 under test may also be connected to the integrated circuit 130″ under test via the probe card 120″ and a bridge unit of the bridge integrated circuit 140.

In the embodiment, the output buffers 135_1 to 135_M are implemented by tri-state buffers, which is given as an example rather than a limitation to the test system of the embodiment. In an alternative embodiment, the output buffers may also be implemented by combinations of switches and buffers, as output buffers 135_1″ to 135_M″ shown in FIG. 4.

In the embodiment, the test apparatus 100 and the probe card 120 of the test system 1 are for testing one integrated circuit 130 under test, which is given as an example rather than a limitation to the test system 100 of the embodiment.

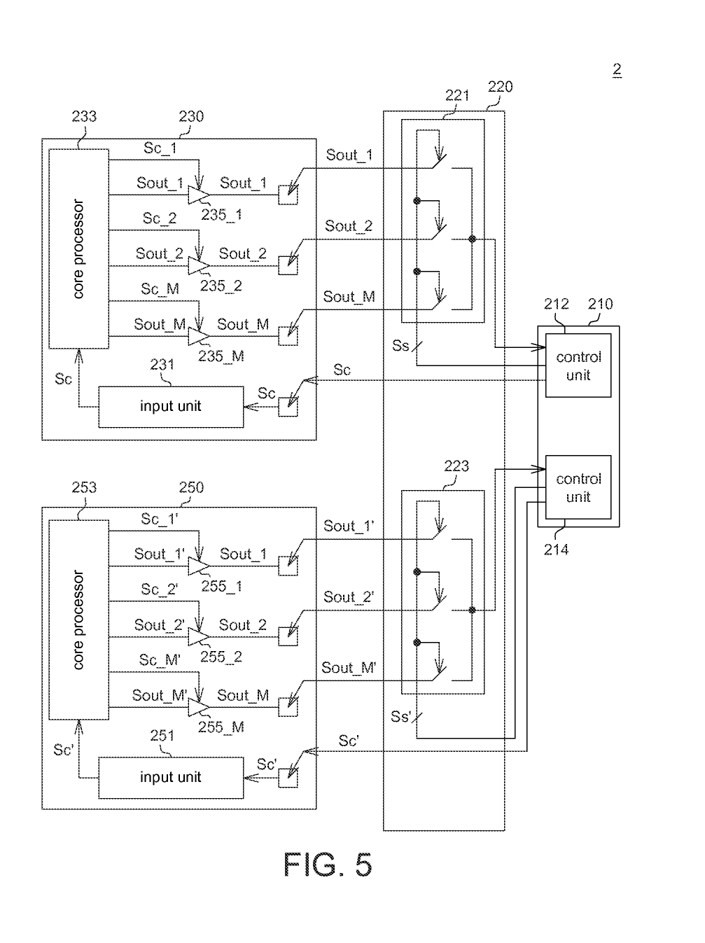

FIG. 5 shows a block diagram of a test system according to another exemplary embodiment. In another embodiment, a test system 2 further includes at least one other integrated circuit 250 under test, a probe card 220 is provided with two switching units 221 and 223, and a test apparatus 210 includes two control units 212 and 214 for respectively performing switching control on integrated circuits 230 and 240 under test. Further, the control unit 214 provides an output control signal Sc′ to the integrated circuit 250 under test to control output switching operations of the integrated circuit 250 under test. Accordingly, the test system 2 of the embodiment is capable of coupling to two or more than two integrated circuits under tests, and selectively controlling time-division multiplexing to perform test operations on the integrated circuits.

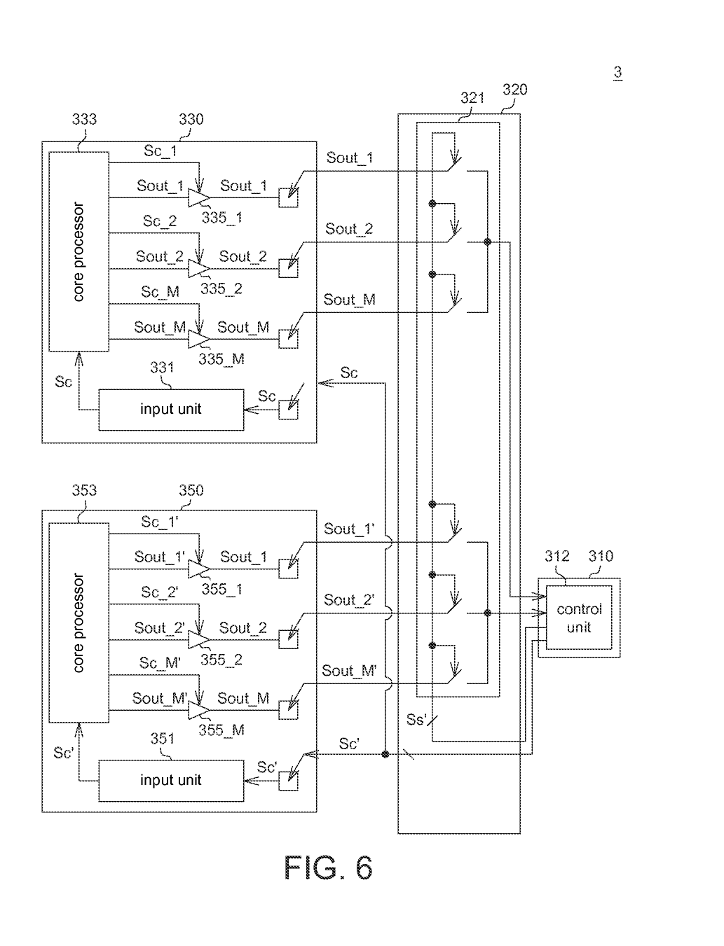

In the embodiment, M=N is taken as an example rather than a limitation to the test system 1 of the embodiment. In an alternative embodiment, the parameter N may substantially be greater than M. Further, the N inputs of a switching unit 321 may be divided into two or more subsets for respectively performing test operations on two or more integrated circuits 330 and 350 under test, as shown in FIG. 6.

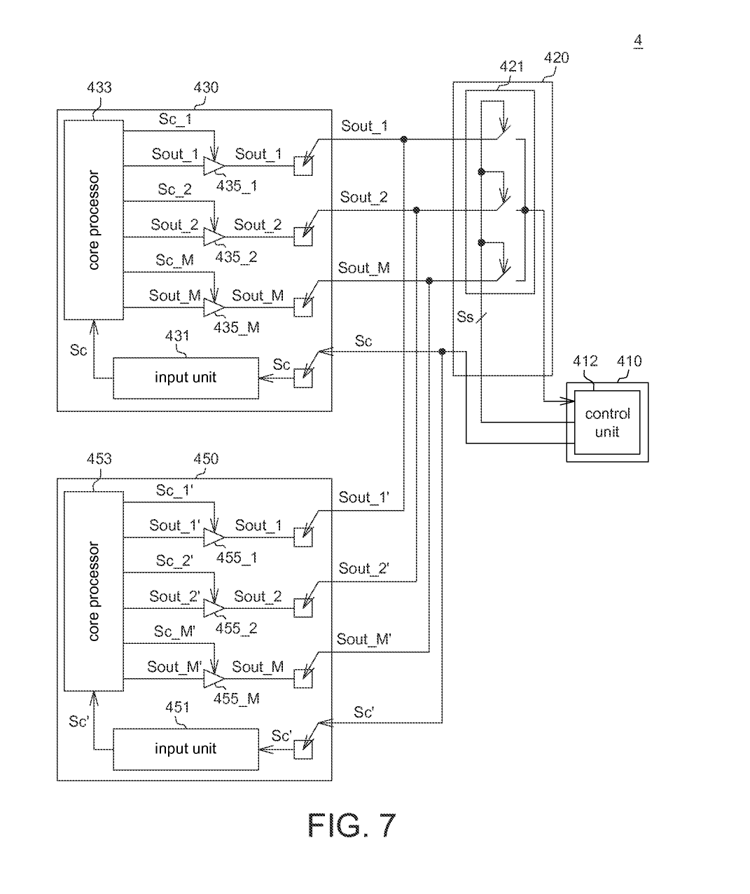

In the embodiment, a one-on-one relationship between the inputs of the switching unit 121 and the output buffers 135_1 to 135M of the integrated circuit 130 under test is given as an example rather than a limitation to the test system 1 of the embodiment. In an alternative embodiment, each of the inputs of a switching unit 421 may correspond to two or more output buffers 435_1 to 435_M and 455_1 to 455_M, as shown in FIG. 7. Taking a situation of each of the inputs of the switching unit 421 concurrently corresponding to two output buffers for example, through switching operations of the switching unit 421 and the output buffers 435_1 to 435_M and 455_1 to 455_M, an output of a probe card 420 is allowed to concurrently transmit output signals provided from 2M output buffers.

While the application has been described by way of example and in terms of the preferred embodiments, it is to be understood that the application is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An integrated circuit, comprising:
an input unit, having an output control pin, for receiving an output control signal;
a core processing unit, coupled to the input unit, for receiving the output control signal and accordingly providing M output control signals, where M is a natural number greater than 1; and
M output buffers, coupled to the core processor, wherein the M output buffers are time-division multiplexing and enabled in response to the M output control signals, respectively, to output M output signals in M operation periods, respectively.

2. The integrated circuit according to claim 1, wherein the output control signal is provided by a test apparatus, and the test apparatus is connected to the integrated circuit via a probe card.

3. The integrated circuit according to claim 2, wherein the probe card comprises:
a switching unit, having N inputs and an output, where N is a natural number greater than or equal to M; and
M inputs among the N inputs are coupled to M output buffers, respectively, the output is coupled to the test apparatus, and the switching unit further selectively couples one of the M inputs to the output in response to a switching control signal provided by the test apparatus.

4. The integrated circuit according to claim 2, wherein the test apparatus further provides at least one second output control signal for another integrated circuit coupled to the probe card, and the test apparatus selectively controls the two integrated circuits to perform time-division multiplexing operations via the probe card.

5. The integrated circuit according to claim 1, wherein the output control signal is provided by a test apparatus, and the test apparatus is connected to the integrated circuit via a bridge integrated circuit and a probe card.

6. The integrated circuit according to claim 5, wherein the bridge integrated circuit comprises:
a switching unit, having N inputs and an output, where N is a natural number greater than or equal to M; and
M inputs among the N inputs are coupled to the M output buffers, respectively, the output is coupled to the test apparatus via the probe card, and the switching unit further selectively couples one of the M inputs to the output in response to a switching control signal provided by the test apparatus.

7. The integrated circuit according to claim 5, wherein the test apparatus further provides at least one second output control signal for another integrated circuit coupled to the bridge integrated circuit, and the test apparatus selectively controls the two integrated circuits to perform time-division multiplexing operations via the bridge integrated circuit and the probe card.

8. A test system, comprising:
a test apparatus, comprising:
a control unit, for providing an output control signal;
a bridge unit, comprising:
a switching unit, having N inputs and an output, where N is a natural number greater than 1; and
an integrated circuit, comprising:
an input unit, having an output control pin, for receiving the output control signal;
a core processor, coupled to coupled to the input unit, for receiving the output control signal and accordingly providing M output control signals, where M is a natural number greater than 1 and smaller than or equal to N; and
M output buffers, coupled to the core processor and coupled to M inputs among the N inputs, wherein the M output buffers are time-division multiplexing and enabled in response to the M output control signals, respectively, to output M output signals in M operation periods to the M inputs, respectively.

9. The test system according to claim 8, wherein the bridge unit comprises:
a probe card, comprising the switching unit, the probe card connected to the integrated circuit and the test apparatus via the switching unit.

10. The test system according to claim 9, wherein M inputs among the N inputs of the switching unit are coupled to the M output buffers, respectively, the output is coupled to the test apparatus, and the switching unit further selectively couples one of the M inputs to the output in response to a switching control signal provided by the test apparatus.

11. The test system according to claim 9, further comprising:
at least another integrated circuit;
wherein, the control unit further provides at least one second output control signal for the another integrated circuit coupled to the bridge integrated circuit, to selectively control the two integrated circuits for time-division multiplexing operations.

12. The test system according to claim 8, wherein the bridge unit comprises:
a bridge integrated circuit, comprising the switching unit; and
a probe card, for coupling the bridge integrated circuit to the test apparatus.

13. The test system according to claim 12, wherein M inputs among the N inputs of the switching unit are coupled to the M output buffers, respectively, the output is coupled to the test apparatus via the probe card, and the switching unit further selectively couples one of the M inputs to the output in response to a switching control signal provided by the test apparatus.

14. The test system according to claim 12, further comprising:
at least another integrated circuit;
wherein, the control unit further provides at least one second output control signal for the another integrated circuit coupled to the bridge integrated circuit and the probe card to selectively control the two integrated circuits for time-division multiplexing operations.
